(19) United States
(12) Patent Application Publication
(10) Pub. No.: US 2026/0059707 A1
(43) Pub. Date: Feb. 26, 2026

(54) ELECTRONIC DEVICE WITH TRIPLE LIQUID COOLING CYCLE

(71) Applicant: Guangzhou NeoGene Thermal Management Technology Co., Ltd., Guangzhou (CN)

(72) Inventor: JEN-SHYAN CHEN, Guangzhou (CN)

(21) Appl. No.: 18/813,068

(22) Filed: Aug. 23, 2024

(51) Int. Cl. H05K 7/20

(52) U.S. Cl. CPC H05K 7/203; H05K 7/20236; H05K 7/20272; H05K 7/20327; H05K 7/20772; H05K 7/20809

(57) ABSTRACT

An electronic device with triple liquid cooling cycle comprises a first sealed case, a circuit motherboard and a liquid cooling module. The first sealed case comprises a first heat exchange cavity, a first liquid inlet, a first liquid outlet, a second liquid inlet and a second liquid outlet. The circuit motherboard is arranged inside the first sealed case and electrically connected to a first heat source. The liquid cooling module is coupled to the first heat source and comprises a first vapor chamber and a second sealed case having a second heat exchange cavity, a third liquid inlet and a third liquid outlet. Wherein, the first heat exchange cavity, the first liquid inlet and the first liquid outlet form a first flow channel for circulating the first cooling liquid; the second heat exchange cavity, the second liquid inlet, the third liquid inlet, the second liquid outlet and the third liquid outlet form a second flow channel for circulating the second cooling liquid; the third cooling liquid inside the first vapor chamber forms a third flow channel with two-phase flow circulation.

### BACKGROUND OF THE INVENTION

### Field of the invention

The embodiment of the present invention relates to an electronic device, particularly to an electronic device with triple liquid cooling cycle. The electronic device integrates the functionalities of a two-phase flow circulation using a vapor chamber, a cooling liquid circulation using a cold plate, and an immersion-type cooling liquid circulation. When the inlet and outlet ports of the electronic device are connected to external cooling liquid circulation systems, the heat generated by various electronic components within the electronic device can be effectively transferred outside the electronic device.

### Description of the prior art

In the prior art, the conventional liquid cooling technologies for data center servers mainly include cold plate liquid cooling and immersion liquid cooling technologies.

In cold plate liquid cooling technology, using cold plates to be installed on a cold plate cooling module on high-performance chips (such as Central Processing Units (CPU), Graphics Processing Units (GPU), and Artificial Intelligence (AI) chips) on the circuit motherboard within a server. Cooling liquid is then delivered to the inlet and outlet of the cooling to achieve heat exchange between the micro channels inside the cold plate and the chips, after which the heated water is carried away from the cold plate, thereby achieving the goal of lowering the temperature of the chips. However, there are several issues in this type of cold plate liquid cooling technology. First, cold plate cooling modules with micro channels have a limit on cooling capacity, which will no longer meet the increasing thermal design power (TDP) requirements of high-performance chips. According to current technology, when the power of a single chip exceeds 500W, conventional cold plates reach their thermal dissipation limits. Second, in addition to the heat generated by high-performance chips that can be managed with cooling modules, there are other electronic heat-generating components arranged in the server. These electronic heat-generating components are only relying on fans for air cooling. However, the heat expelled by the fans is released into the server room of the data center, which increases temperature. Therefore, air conditioning is required to lower the room temperature, which causes a bottleneck for reducing the overall Power Usage Effectiveness (PUE) of the data center.

In immersion liquid cooling technology, directly immersing the entire circuit motherboard and electronic heat-generating components of a server into a non-conductive liquid, which directly transfers the heat generated during server operation to the cooling liquid. Immersion cooling technologies in the prior art can be categorized into the following two types based on operational principles: (1)single-phase immersion liquid cooling technology: this method involves immersing the heat source into a dielectric liquid with high boiling points and low viscosity, such as hydrocarbon compounds. A circulation pump is installed within the liquid tank to promote fluid circulation; (2)two-phase immersion liquid cooling technology: this method involves immersing the heat source into a low-viscosity, non-conductive cooling liquid. As the liquid undergoes low-temperature boiling, heat is transferred from the liquid pool to the external space through heat exchange, such through via condenser tubes. The vapor then cools and condenses, flowing back into the cooling liquid pool. This continuous cycle effectively dissipates heat.

However, the cooling liquid used in two-phase immersion cooling systems (i.e., perfluorocarbons) is a synthetic harmful chemical. During the heat dissipation process, vaporized perfluorocarbons can spread through the air, potentially causing corrosion and contamination to personnel, the environment, or equipment.

Furthermore, with advancements in technology and consumer demand, the performance requirements for electronic chips are increasing. For example, in data center servers, individual chips reach power levels of 500W or 700W, and future designs may require chips exceeding 1000W. In general, Power Usage Effectiveness (PUE) is commonly used to measure and calculate the energy efficiency of data centers. A lower PUE value indicates less power consumption, with an ideal PUE value being 1 (i.e., electrical energy is 100% converted to computing usage). However, in practical applications, servers generate significant amounts of heat during operation, which can lead to overheating or even damage to the chips without an effective cooling system. Therefore, it is necessary to design more efficient cooling devices and systems to address the limitations of conventional technologies and to support the future development of high-performance chips. Moreover, these cooling systems should reduce the PUE value closer to 1, thereby lowering electricity costs while also meeting environmental sustainability requirements.

### SUMMARY OF THE INVENTION

Therefore, the present invention provides an electronic device with a triple liquid cooling cycle, which allows the server itself to be made into a standalone electronic device that combines the cooling effects of both cold plate and immersion liquid cooling. When the liquid inlet and outlet of the server are connected to an external circulating cooling liquid, the heat generated by all electronic components within the server can be efficiently transferred and discharged outside the server cabinet, or even transferred and discharged outside the data center for centralized processing and effective utilization. This significantly improves the overall cooling efficiency of the server and reduces the PUE value of the entire data center, thereby addressing the aforementioned issues in conventional technology.

The present invention provides the electronic device with triple liquid cooling cycle includes a first sealed case, a circuit motherboard, and a liquid cooling module. The first sealed case includes a first heat exchange cavity, a first liquid inlet, a first liquid outlet, a second liquid inlet and a second liquid outlet. Wherein, the first liquid inlet and the first liquid outlet are respectively communicated with the first heat exchange cavity. The circuit motherboard is arranged inside the first sealed case and electrically connected to a first heat source. The liquid cooling module is coupled to the first heat source and includes a first vapor chamber and a second sealed case. The second sealed case has a second heat exchange cavity, a third liquid inlet and a third liquid outlet. The third liquid inlet and third liquid outlet are respectively communicated with the second liquid inlet and the second liquid outlet, the first vapor chamber is arranged inside the second sealed case and has a heat evaporation end and a condensation end. Wherein, the first heat exchange cavity, the first liquid inlet and the first liquid outlet form a first flow channel for circulating the first cooling liquid; the second heat exchange cavity, the second liquid inlet, the third liquid inlet, the second liquid outlet and the third liquid outlet form a second flow channel for circulating the second cooling liquid; the third cooling liquid inside the first vapor chamber forms a third flow channel with two-phase flow circulation.

Wherein, the first sealed case is a sealed case with 1U size, and the electronic device can be installed in a modular server rack. Wherein, the electronic device can be a server or a communication device.

Wherein, the electronic device further comprises a circuit sub board electrically connected to the circuit motherboard. Wherein, the first heat source is arranged on the circuit sub board, wherein the circuit sub board, the first heat source, and the liquid cooling module form an electronic component with cooling functions.

Wherein, the circuit sub board further includes a second heat source, the liquid cooling module includes a copper top cover and a copper bottom cover. The copper bottom cover has a first zone corresponding to the copper top cover and a second zone. The first zone has a first lower surface, and the second zone has a second lower surface and a second upper surface. When the copper top cover and the copper bottom cover are coupled together, a first vapor chamber is formed. Wherein, the first lower surface of the first zone is configured to contact the first heat source, and the second lower surface of the second zone is configured to contact the second heat source.

Wherein, the electronic component further includes a semi-open shell connected to the copper bottom cover to form the second sealed case and the second heat exchange cavity. The second heat exchange cavity is configured to accommodate the copper top cover and the second upper surface of the second zone, and both the third liquid inlet and third liquid outlet are arranged on the semi-open shell.

Wherein, the electronic component further includes a two-dimensional vapor chamber, formed in the second zone of the copper bottom cover, having a second vapor chamber cavity and a vapor chamber lower surface for contacting the second heat source.

Wherein, the two-dimensional vapor chamber includes a plate, which is corresponding to the second zone of the copper bottom cover, the second zone has a bottom cover cavity. When the plate and the second zone of the copper bottom cover are coupled together, the bottom cover cavity forms the second vapor chamber cavity.

Wherein, the copper top cover includes a base plate and a tubular component. The base plate has a base plate cavity, an opening, and an upper outer surface. The tubular component has a tubular component cavity, the tubular component is arranged on the upper outer surface of the base plate, and located above the opening, and the tubular component protrudes outward from the upper outer surface. Wherein when the copper top cover is coupled to the first zone of the copper bottom cover, the tubular component cavity and the base plate cavity form an air chamber of the first vapor chamber.

Wherein, the first cooling liquid is a non-conductive single-phase or dual-phase cooling liquid, the second cooling liquid is water or a water-alcohol mixture, and the third cooling liquid is pure water.

Wherein, the first flow channel is formed by connecting the first liquid inlet, the first heat exchange cavity, and the first liquid outlet through a first connecting pipe; the second flow channel is formed by connecting the second liquid inlet, the third liquid inlet, the second heat exchange cavity, the third liquid outlet, and the second liquid outlet through a second connecting pipe; the third cooling liquid inside the first vapor chamber forms the third flow channel with two-phase flow circulation.

In summary, the present invention provides an electronic device with triple liquid cooling cycle, which utilizes the triple liquid cooling cycles within the device to achieve enhanced heat exchange and heat transfer for improved cooling and energy-saving effects. Compared with the prior art, the present invention provides several advantages: First, the invention integrates three liquid cooling cycles into the electronic device, with one two-phase liquid cooling cycle corresponding to a vapor chamber, which can directly transfer heat exchange and heat transfer for the first heat source (ie, main heat source). Then, the absorbed heat is rapidly transferred from the heat-absorbing end to the condensing end through phase change. Another cycle corresponds to the second sealed casing, conducting heat exchange and heat transfer between the vapor chamber and the cooling liquid within the second heat exchange cavity. The third cycle corresponds to the first sealed casing, which is positioned across the entire circuit motherboard, conducting heat exchange and heat transfer for the heat-generating components (secondary heat sources) on the motherboard.

Therefore, when this invention is applied to an electronic device, the triple liquid cooling cycle essentially provides three stacked heat exchange systems, dissipating heat from the inside out through tiered liquid cooling cycles. This significantly enhances the heat transfer and cooling efficiency of the electronic device itself.

In conclusion, the electronic device with a triple liquid cooling cycle, of the invention, effectively utilizes the three-tiered liquid cooling cycles to perform heat exchange and heat transfer for both the main and secondary heat sources, so as to reach superior cooling performance. The electronic device with triple liquid cooling cycle of the present invention not only significantly increases the cooling efficiency of the electronic device, making the PUE value approach 1, but also helps reduce the cost of cooling liquid usage.

### BRIEF DESCRIPTION OF THE APPENDED DRAWINGS

FIG. 1 is a sectional diagram illustrating the electronic device with triple liquid cooling cycle according to an embodiment of the present invention.

FIG. 2 is a top view illustrating the electronic device according to FIG. 1.

FIG. 3 is a schematic diagram illustrating the electronic device with triple liquid cooling cycle according to another embodiment of the present invention.

FIG. 4 is a sectional diagram illustrating the electronic component of the electronic device according to another embodiment of the present invention.

FIG. 5 is a sectional diagram illustrating the first vapor chamber of FIG. 4.

FIG. 6 is an enlarged diagram of region B of FIG. 5.

FIG. 7 is a sectional diagram illustrating the first vapor chamber according to another embodiment of the present invention.

FIG. 8 is an enlarged diagram of region B of FIG. 7.

FIG. 9 is a sectional diagram illustrating the first vapor chamber of FIG. 1.

### DETAILED DESCRIPTION OF THE INVENTION

For the sake of the advantages, spirits and features of the present invention can be understood more easily and clearly, the detailed descriptions and discussions will be made later by way of the embodiments and with reference of the diagrams. It is worth noting that these embodiments are merely representative embodiments of the present invention, wherein the specific methods, devices, conditions, materials and the like are not limited to the embodiments of the present invention or corresponding embodiments. Moreover, the devices in the figures are only used to express their corresponding positions and are not drawing according to their actual proportion.

In the description of the present invention, it is to be understood that the orientations or positional relationships of the terms "longitudinal, lateral, upper, lower, front, rear, left, right, top, bottom, inner, outer" and the like are based on the orientation or positional relationship shown in the drawings. It is merely for the convenience of the description of the present invention and the description of the present invention, and is not intended to indicate or imply that the device or component referred to has a specific orientation, is constructed and operated in a specific orientation, and therefore cannot be understood as limitations of the invention.

In the description of this specification, the description with reference to the terms "a specific embodiment", "another specific embodiment" or "parts of specific embodiments" etc. means that the specific feature, structure, material or feature described in conjunction with the embodiment include in at least one embodiment of the present invention. In this specification, the schematic representations of the above-mentioned terms do not necessarily refer to the same embodiment. Moreover, the described specific features, structures, materials or characteristics can be combined in any one or more embodiments in a suitable manner.

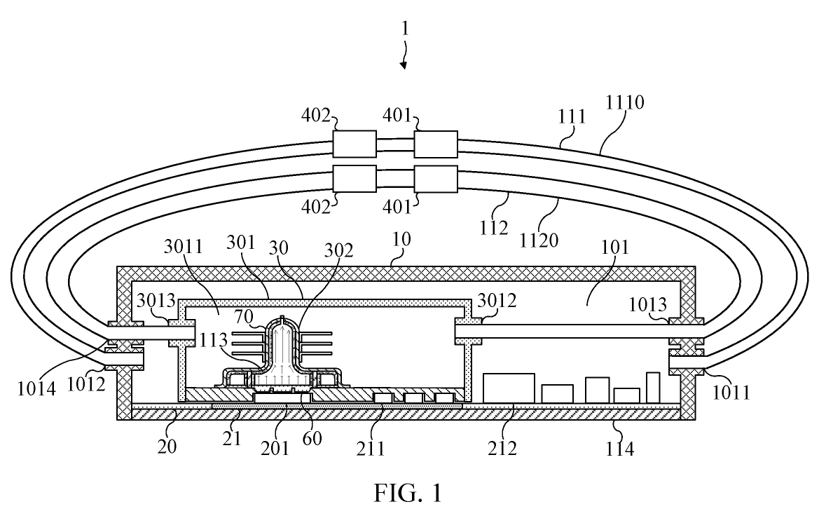

Please refer to FIG. 1. FIG. 1 is a sectional diagram illustrating the electronic device 1 with triple liquid cooling cycle according to an embodiment of the present invention. As shown in FIG. 1, the present invention provides an electronic device 1 with triple liquid cooling cycle, which includes a first sealed case 10, a circuit motherboard 20, and a liquid cooling module 30. The first sealed case 10 has a first heat exchange cavity 101, a first liquid inlet 1011, a first liquid outlet 1012, a second liquid inlet 1013, and a second liquid outlet 1014. The first liquid inlet 1011 and the first liquid outlet 1012 respectively communicate with the first heat exchange cavity 101. The circuit motherboard 20 is arranged inside the first sealed case 10 and is located within the first heat exchange cavity 101. The circuit motherboard 20 is electrically connected to a first heat source 201. The liquid cooling module 30 is coupled to the first heat source 201 and includes a second sealed case 301 and a first vapor chamber 302. The second sealed case 301 has a second heat exchange cavity 3011, a third liquid inlet 3012, and a third liquid outlet 3013. The third liquid inlet 3012 and third liquid outlet 3013 respectively communicate with the second liquid inlet 1013 and the second liquid outlet 1014. Additionally, the first vapor chamber 302 is arranged inside the second sealed case 301 and can contact the cooling liquid in the second heat exchange cavity 3011 for heat exchange. Wherein, the first heat exchange cavity 101, the first liquid inlet 1011, and the first liquid outlet 1012 form a first flow channel 111 for circulating the first cooling liquid; the second heat exchange cavity 3011, the second liquid inlet 1013, the third liquid inlet 3012, the second liquid outlet 1014, and the third liquid outlet 3013 form a second flow channel 112 for circulating the second cooling liquid; the third cooling liquid inside the first vapor chamber 302 forms a third flow channel 113 with two-phase flow circulation. Moreover, the heat evaporation end 60 of the first vapor chamber 302 is attached to the first heat source 201, and the condensation end 70 of the first vapor chamber 302 is immersed in the second cooling liquid.

The operation of the third flow channel 113 will be described in detail below. Please refer to FIG. 1 again, as shown in FIG. 1, the cooling liquid in the third flow channel 113 flows through the capillary structure inside the first vapor chamber 302. In practice, when the heat evaporation end of the first vapor chamber 302 receives heat from the first heat source 201, the cooling liquid in the third flow channel 113 absorbs the heat and turns into a gas, flowing upward inside the first vapor chamber 302 as shown by the upward arrow in FIG. 1. Then, at the condensation end 70, the gas-phase cooling liquid reverts to liquid phase and flows downward along the downward arrow inside the first vapor chamber 302, driven by capillary action, returning the working fluid to the heat evaporation end 60 to complete the two-phase flow circulation.

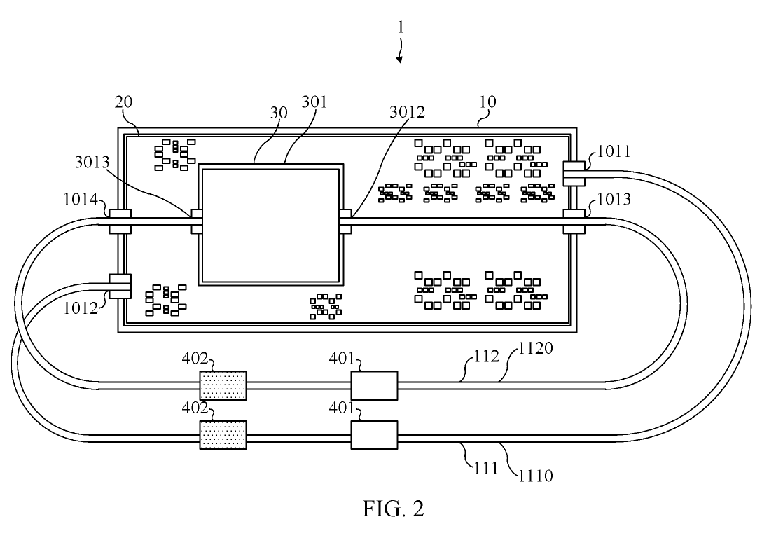

Please refer to FIG. 1 and 2 together. FIG. 2 is a top view illustrating the electronic device 1 according to FIG. 1. As shown in FIG. 2, the first liquid inlet 1011 and first liquid outlet 1012 form the first flow channel 111; the second liquid inlet 1013, the third liquid inlet 3012, the second liquid outlet 1014, and the third liquid outlet 3013 form the second flow channel 112. From the top view, the positions are clearly shown, with pumps 401 provided in each of the first flow channel 111 and the second flow channel 112 to drive the cooling liquid in and out of the inlets and outlets, so as to enhance the heat exchange efficiency within the first heat exchange cavity 101 and the second heat exchange cavity 3011. It should be noted that the cooling liquid in the third flow channel 113 flows in a two-phase cycle between the heat evaporation end 60 and the condensation end 70 within the first vapor chamber 302, as shown in FIG. 1. In practice, the first flow channel 111 is formed by connecting the first liquid inlet 1011, the first heat exchange cavity 101, and the first liquid outlet 1012 through the first connecting pipe 1110. The second flow channel 112 is formed by connecting the second liquid inlet 1013, the third liquid inlet 3012, the second heat exchange cavity 3011, the third liquid outlet 3013, and the second liquid outlet 1014 through the second connecting pipe 1120.

Wherein, the positions of the first liquid inlet 1011, the first liquid outlet 1012, the second liquid inlet 1013, the third liquid inlet 3012, the second liquid outlet 1014, and the third liquid outlet 3013 as shown in FIG. 2 are not limited hereto and can be designed according to actual server requirements. Moreover, in practice, the size of the first sealed case 10 of the electronic device 1 with triple liquid cooling cycle of the present invention is a sealed case with 1U size and can be installed in a modular server rack. However, the size is not limited hereto; it can also be a 2U size specification or custom-designed according to the requirements of specific servers. Additionally, the electronic device with triple liquid cooling cycle of the present invention is not only applied to server applications but can also be applied in any electronic device, communication device, or automotive device.

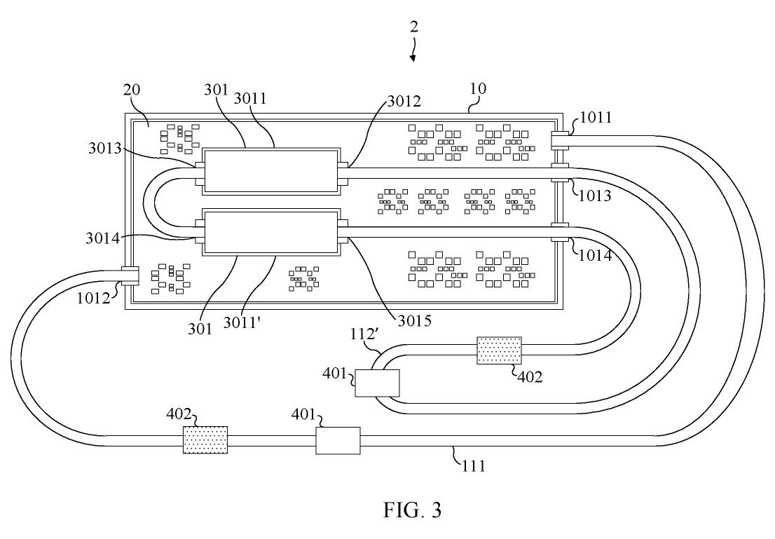

The electronic device with triple liquid cooling cycle of the present invention not only can be applied to commonly available specifications on the market (i.e., a circuit motherboard with only one main heat source), but also can be applied to a circuit motherboard with two or more main heat sources. Please refer to FIG. 3. FIG. 3 is a schematic diagram illustrating the electronic device with triple liquid cooling cycle according to another embodiment of the present invention. As shown in FIG. 3, when there are two main heat sources (not shown), a second heat exchange cavity 3011, 3011' can be installed on these two main heat sources, and the second flow channel 112' can be formed by connecting the second liquid inlet 1013, the third liquid inlet 3012, the second heat exchange cavity 3011, the third liquid outlet 3013, the fourth liquid inlet 3014, the second heat exchange cavity 3011', the fourth liquid outlet 3015, and the second liquid outlet 1014 to circulate the second cooling liquid.

In practice, the first cooling liquid is a non-conductive single-phase or dual-phase cooling liquid, the second cooling liquid is water or a water-alcohol mixture, and the third cooling liquid is pure water, but the materials for the cooling liquids are not limited hereto. It should be noted that water is chosen as the third cooling liquid because water has a high latent heat of vaporization, allowing to quickly and efficiently dissipate the heat generated by the first heat source 201. The first heat exchange cavity 101 and the second heat exchange cavity 3011, 3011' are respectively filled with the first cooling liquid and the second cooling liquid, which can carry away the absorbed heat through circulation. Wherein, the first sealed case 10 can be welded to the base plate 114 to improve the sealing of the first heat exchange cavity 101 and prevent leakage of the first cooling liquid, but the joining process is not limited to welding.

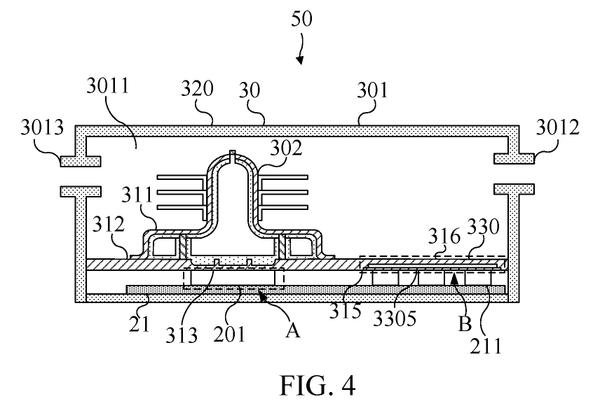

In the present invention, the first heat source can be directly arranged on the circuit motherboard or mounted on the circuit motherboard by using a socket. Please refer to FIG. 4. FIG. 4 is a sectional diagram illustrating the electronic component of the electronic device according to another embodiment of the present invention. As shown in FIG. 4, the electronic device 1 with triple liquid cooling cycle according to another specific embodiment of the present invention also includes a circuit sub board 21 electrically connected to the circuit motherboard (not shown), with the first heat source 201 installed on the circuit sub board 21. The circuit sub board 21, the first heat source 201, and the liquid cooling module 30 form an electronic component 50 with cooling functions. In practice, the circuit sub board 21 can be designed as a plate and installed on the circuit motherboard (not shown) using a slot.

In addition to the main heat source with higher power, sometimes a secondary heat source with lower power is also located near the main heat source. The following will provide a detailed explanation of the first vapor chamber 302, which can be used for cooling both the main and secondary heat sources. Please continue to refer to FIG. 4. A second heat source 211 is additionally installed on the circuit sub board 21, and the liquid cooling module 30 includes a copper top cover 311 and a copper bottom cover 312. The copper bottom cover 312 has a first zone A corresponding to the copper top cover 311 and a second zone B. The first zone A has a first lower surface 313, and the second zone B has a second lower surface 315 and a second upper surface 316. When the copper top cover 311 and the copper bottom cover 312 are coupled together, a first vapor chamber 302 is formed. Wherein, the first lower surface 313 of the first zone A is used to contact the first heat source 201, and the second lower surface 315 of the second zone B is used to contact the second heat source 211. In specific embodiments, the first vapor chamber 302 is a three-dimensional vapor chamber but can also be a two-dimensional vapor chamber.

The electronic component 50 further includes a semi-open shell 320, which is connected to the copper bottom cover 312 to form the second sealed case 301 and the second heat exchange cavity 3011. The second heat exchange cavity 3011 is used to accommodate the copper top cover 311 and the second upper surface 316 of the second zone B, and both the third liquid inlet 3012 and third liquid outlet 3013 are arranged on the semi-open shell 320. In practice, the first heat source 201 is the main heat source (such as a high-power CPU chip, GPU chip, AI chip, or IGBT chip), and the second heat source 211 is a lower-power secondary heat source (such as a passive component or memory). As shown in FIG. 4, the electronic component 50 can be installed in FIG. 1 to form an electronic device with triple liquid cooling cycle. Please refer to FIG. 1 and FIG. 4. Considering that the temperature caused by the actual heat generated from the secondary heat source is lower than that of the primary heat source. If the first zone A is positioned near the third liquid inlet 3012, the temperature of the second cooling liquid rises significantly after absorbing the heat from the primary heat source 201 in the first zone A, the temperature increase will be much greater than that of the secondary heat source 211. In this case, not only would the second zone B fail to effectively dissipate heat, but it might also cause the temperature of the secondary heat source 211 to rise. Therefore, the second zone B of the first vapor chamber 302 is arranged closer to the third liquid inlet 3012 in this invention. In practice, the flow direction of the second cooling liquid is not limited hereto.

Wherein, the electronic component 50 of the electronic device with triple liquid cooling cycle of the invention also includes a two-dimensional vapor chamber 330. The two-dimensional vapor chamber 330 can simultaneously dissipate heat for certain secondary heat sources with higher power. The detail for setting up the two-dimensional vapor chamber 330 will be further explained below.

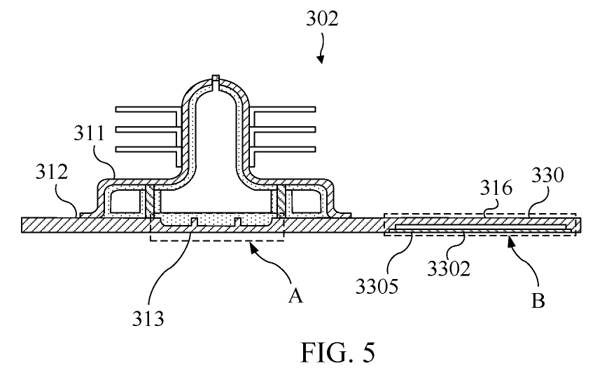

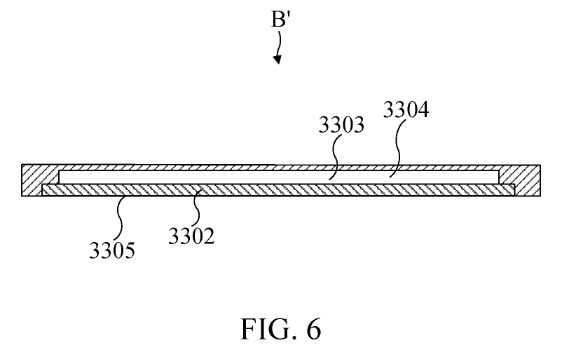

Please refer to FIG. 4, FIG. 5, and FIG. 6. FIG. 5 is a sectional diagram illustrating the first vapor chamber of FIG. 4. FIG. 6 is an enlarged diagram of the region B of FIG. 5. As shown in FIG. 4 and FIG. 5, the two-dimensional vapor chamber 330 is formed in the second zone B of the copper bottom cover 312. The second zone B can dissipate heat for the second heat source 211. Please further refer to FIG. 5 and FIG. 6. As shown in FIG. 6, the two-dimensional vapor chamber 330 includes a plate 3302, corresponding to the second zone B of the copper bottom cover 312, the second zone B has a bottom cover cavity 3303. The bottom cover cavity 3303 forms the second vapor chamber cavity 3304 when the plate 3302 and the second zone B of the copper bottom cover 312 are coupled together. In this specific embodiment, the plate lower surface 3305 of the plate 3302 is used to contact the second heat source 211. Therefore, in this specific embodiment, the plate lower surface 3305 of the plate 3302 and the second lower surface 315 of the copper bottom cover 312 are coplanar.

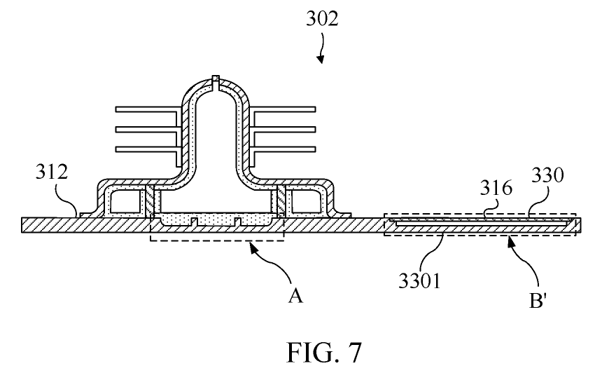

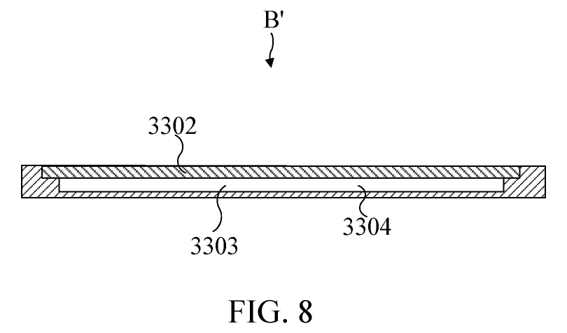

In addition to the method mentioned above, where the plate 3302 is installed on the copper bottom cover 312, another embodiment of installing the plate 3302 on the copper bottom cover 312 will be introduced below. Please refer to FIG. 7 and FIG. 8. FIG. 7 is a sectional diagram illustrating the first vapor chamber according to another embodiment of the present invention. FIG. 8 is an enlarged diagram of region B of FIG. 7. As shown in FIG. 7 and 8, when the plate 3302 is coupled to the second zone B', the bottom cover cavity 3303 forms the second vapor chamber cavity 3304, and the plate 3302 is located at the second upper surface 316. At this time, the vapor chamber lower surface 3301 is used to contact the second heat source 211.

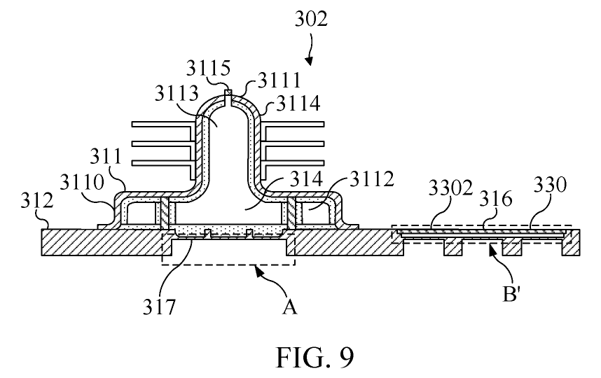

Please refer to FIG. 9. FIG. 9 is a sectional diagram illustrating the first vapor chamber of FIG. 1. As shown in FIG. 9, grooves 317 can be milled out by a Computer Numerical Control (CNC) machine. These multiple grooves 317 are positioned within the first zone A and the second zone B of the copper bottom cover 312. The grooves 317 can be processed according to the number and height of the first heat source (not shown) and the second heat source (not shown) to make the depth of the grooves 317 better match the height of the first heat source (not shown) and the second heat source, thereby conducting heat more efficiently. It should be noted that the plate 3302 of the two-dimensional vapor chamber 330 is also arranged on the second upper surface 316. Wherein, the installation method of the plate 3302 is generally the same as previously described and will not be repeated here.

Please refer to FIG. 9 again. As shown in FIG. 9, the copper top cover 311 includes a base plate 3110 and a tubular component 3111. The base plate 3110 has a base plate cavity 3112, an opening (not marked), and an upper outer surface(not marked). The tubular component 3111 has a tubular component cavity 3113. The tubular component 3111 is arranged on the upper outer surface of the base plate 3110, located above the opening, and protrudes outward from the upper outer surface (as shown in FIG. 9). When the copper top cover 311 is coupled to the first zone A of the copper bottom cover 312, the tubular component cavity 3113 and the base plate cavity 3112 form the air chamber 314 of the first vapor chamber 302. In practice, the tubular component 3111 can be formed integrally by stretching a metal sheet through continuous stamping, making the tubular component 3111 part of the copper top cover 311. The shape of the tubular component 3111 can be cylindrical, rectangular, elliptical, or conical, but is not limited hereto.

Furthermore, the tubular component 3111 has a top end 3114, and the top end 3114 includes an injection port sealing structure 3115. The injection port sealing structure 3115 is formed after injecting the third cooling liquid into the first vapor chamber 302 through a pre-installed liquid injection port at the top end 3114 and then sealing the liquid injection port. In practical applications, the liquid injection port can be sealed by welding or other methods. Additionally, in this specific embodiment, the injection port sealing structure 3115 and the liquid injection port are located at the top end 3114 of the tubular component 3111, but in practical applications, this is not limited hereto; the injection port sealing structure 3115 and the liquid injection port can also be arranged at any position on the tubular component 3111. Furthermore, the manufacturing process of the first vapor chamber 302 in other embodiments of the present invention (i.e., FIG. 5 and 7) is the same as described above and will not be repeated here.

In summary, the present invention provides the electronic device with triple liquid cooling cycle. The electronic device with triple liquid cooling cycle first efficiently transfers the heat generated by high-power-density components through phase changes in the two-phase flow circulation of the third flow channel in the vapor chamber, which causes the third cooling liquid in the heat evaporation zone capillary structure within the vapor chamber to undergo phase change and efficiently transfer the heat. Next, the electronic device with triple liquid cooling cycle efficiently transfers the heat by using the second cooling liquid for heat exchange in the second heat exchange cavity of the second flow channel. Moreover, the heat generated by secondary heat sources on the circuit motherboard with lower power, which is the residual heat not carried away, can be carried away by the non-conductive first cooling liquid circulating in the first flow channel in the first heat exchange cavity, so as to provide the electronic device better cooling efficiency. Compared with the prior art, the electronic device with triple liquid cooling cycle of the invention integrates the circuit motherboard, all heat sources and the cooling system to form an electronic device with its own liquid cooling function. This electronic device can be a server or a communication switch, and in practical applications, the electronic device can be directly stacked and installed in a cabinet, with external cooling liquid circulation systems connected separately to achieve self-cooling function for the device. The electronic device with triple liquid cooling cycle of the present invention not only significantly increases the cooling efficiency of the electronic device, making the PUE value approach 1, but also helps reduce the cost of cooling liquid usage.

With the examples and explanations mentioned above, the features and spirits of the invention are hopefully well described. More importantly, the present invention is not limited to the embodiment described herein. Those skilled in the art will readily observe that numerous modifications and alterations of the device may be made while retaining the teachings of the invention. Accordingly, the above disclosure should be construed as limited only by the metes and bounds of the appended claims.

What is claimed is:

1. An electronic device with triple liquid cooling cycle, comprising:
a first sealed case, having a first heat exchange cavity, a first liquid inlet, a first liquid outlet, a second liquid inlet, and a second liquid outlet, wherein the first liquid inlet and the first liquid outlet are respectively communicated with the first heat exchange cavity;
a circuit motherboard, arranged inside the first sealed case and located within the first heat exchange cavity, and electrically connected to a first heat source; and
a liquid cooling module, coupled to the first heat source and comprising a first vapor chamber and a second sealed case, the second sealed case having a second heat exchange cavity, a third liquid inlet, and a third liquid outlet, the third liquid inlet and third liquid outlet respectively being communicated with the second liquid inlet and the second liquid outlet, the first vapor chamber being arranged inside the second sealed case and having a heat evaporation end and a condensation end;
wherein, the first heat exchange cavity, the first liquid inlet, and first liquid outlet form a first flow channel for circulating the first cooling liquid; the second heat exchange cavity, the second liquid inlet, the third liquid inlet, the second liquid outlet, and the third liquid outlet form a second flow channel for circulating the second cooling liquid; the third cooling liquid inside the first vapor chamber forms a third flow channel with two-phase flow circulation, the heat evaporation end of the first vapor chamber is attached to the first heat source, and the condensation end of the first vapor chamber is immersed in the second cooling liquid.

2. The electronic device with triple liquid cooling cycle of claim 1, wherein the first sealed case is a sealed case with 1U size, and the electronic device can be installed in a modular server rack, wherein the electronic device can be a server or a communication device.

3. The electronic device with triple liquid cooling cycle of claim 1 further comprising a circuit sub board electrically connected to the circuit motherboard, wherein the first heat source is arranged on the circuit sub board, wherein the circuit sub board, the first heat source, and the liquid cooling module form an electronic component with cooling functions.

4. The electronic device with triple liquid cooling cycle of claim 3, wherein the circuit sub board further comprises a second heat source, the liquid cooling module comprises a copper top cover and a copper bottom cover, the copper bottom cover has a first zone corresponding to the copper top cover and a second zone, the first zone has a first lower surface, and the second zone has a second lower surface and a second upper surface, when the copper top cover and the copper bottom cover are coupled together, a first vapor chamber is formed, wherein the first lower surface of the first zone is configured to contact the first heat source, and the second lower surface of the second zone is configured to contact the second heat source.

5. The electronic device with triple liquid cooling cycle of claim 4, wherein the electronic component further comprises a semi-open shell connected to the copper bottom cover to form the second sealed case and the second heat exchange cavity, the second heat exchange cavity is configured to accommodate the copper top cover and the second upper surface of the second zone, and both the third liquid inlet and third liquid outlet are arranged on the semi-open shell.

6. The electronic device with triple liquid cooling cycle of claim 5, wherein the electronic component further comprises a two-dimensional vapor chamber, formed in the second zone of the copper bottom cover, having a second vapor chamber cavity and a vapor chamber lower surface for contacting the second heat source.

7. The electronic device with triple liquid cooling cycle of claim 6, wherein the two-dimensional vapor chamber comprises a plate, corresponding to the second zone of the copper bottom cover, the second zone has a bottom cover cavity, when the plate and the second zone of the copper bottom cover are coupled together, the bottom cover cavity forms the second vapor chamber cavity.

8. The electronic device with triple liquid cooling cycle of claim 4, wherein the copper top cover comprises a base plate and a tubular component, the base plate has a base plate cavity, an opening, and an upper outer surface, the tubular component has a tubular component cavity, the tubular component is arranged on the upper outer surface of the base plate, and located above the opening, and the tubular component protrudes outward from the upper outer surface; wherein when the copper top cover is coupled to the first zone of the copper bottom cover, the tubular component cavity and the base plate cavity form an air chamber of the first vapor chamber.

9. The electronic device with triple liquid cooling cycle of claim 1, wherein the first cooling liquid is a non-conductive single-phase or dual-phase cooling liquid, the second cooling liquid is water or a water-alcohol mixture, and the third cooling liquid is pure water.

10. The electronic device with triple liquid cooling cycle of claim 1, wherein the first flow channel is formed by connecting the first liquid inlet, the first heat exchange cavity, and the first liquid outlet through a first connecting pipe; the second flow channel is formed by connecting the second liquid inlet, the third liquid inlet, the second heat exchange cavity, the third liquid outlet, and the second liquid outlet through a second connecting pipe; the third cooling liquid inside the first vapor chamber forms the third flow channel with two-phase flow circulation.
